(19) United States
(12) Patent Application Publication
(10) Pub. No.: US 2014/0349440 A1
(43) Pub. Date: Nov. 27, 2014

(54) PLANARIZATION METHOD

(71) Applicant: CANON KABUSHIKI KAISHA, Tokyo (JP)

(72) Inventor: Atsushi Kanome, Tokyo (JP)

(73) Assignee: CANON KABUSHIKI KAISHA, Tokyo (JP)

(21) Appl. No.: 14/277,225

(22) Filed: May 14, 2014

(30) Foreign Application Priority Data
May 22, 2013 (JP) 2013-108369

(51) Int. Cl. H01L 27/146

(52) U.S. Cl. CPC H01L 27/14683
USPC 438/73

(57) ABSTRACT

A method of planarizing a member is provided. The method includes forming the member and polishing a top face of the member. The forming the member includes forming a resist layer which varies in thickness and performing an etch-back process. The etch-back process removes the resist layer and adjusts amounts to be removed by the polishing from respective locations of the member.

### BACKGROUND OF THE INVENTION

1. Field of the Invention

The present invention relates to a planarization method.

2. Description of the Related Art

Chemical mechanical polishing (CMP) is known as a technique for planarizing surfaces in production of semiconductor devices. However, a polishing rate varies with film position due to various factors such as the size and density of patterns formed on a film to be polished, and consequently a sufficiently planar surface is not available in some cases even if CMP is performed. Thus, Japanese Patent Laid-Open No. 2004-153276 proposes a method of adjusting the polishing rate by using the density and size of pillars formed of silicon nitride on a film to be polished.

### SUMMARY OF THE INVENTION

According to an aspect of the present invention, a method of planarizing a member is provided. The method includes forming the member and polishing a top face of the member. The forming the member includes forming a resist layer which varies in thickness and performing an etch-back process. The etch-back process removes the resist layer and adjusts amounts to be removed by the polishing from respective locations of the member.

Further features of the present invention will become apparent from the following description of exemplary embodiments (with reference to the attached drawings).

### BRIEF DESCRIPTION OF THE DRAWINGS

FIGS. 1A to 1G are diagrams illustrating a planarization method according to some embodiments.

FIG. 2 is a diagram illustrating a method of forming a resist layer according to some embodiments.

FIGS. 3A to 3G are diagrams illustrating a planarization method according to some other embodiments.

FIGS. 4A to 4E are diagrams illustrating a planarization method according to some other embodiments.

FIGS. 5A to 5G are diagrams illustrating a planarization method according to some other embodiments.

FIGS. 6A and 6B are diagrams illustrating a method of manufacturing a solid-state image sensor according to some other embodiments.

### DESCRIPTION OF THE EMBODIMENTS

With the method according to Japanese Patent Laid-Open No. 2004-153276, since the pillars are polished, there is a possibility that the surface will be scratched after the polishing. Thus, same embodiments of the present invention propose a technique advantageous in forming a planar surface by polishing.

Embodiments of the present invention will be described below with reference to the accompanying drawings. Throughout various embodiments, similar components are denoted by the same reference numerals, and redundant description thereof will be omitted. Also, each embodiment can be changed as appropriate, and different embodiments can be used in combination. The following embodiments relate to a planarization method for planarizing a surface of an object by polishing. In the following description, CMP is used as an example of polishing, but the present invention is also applicable to polishing methods other than CMP.

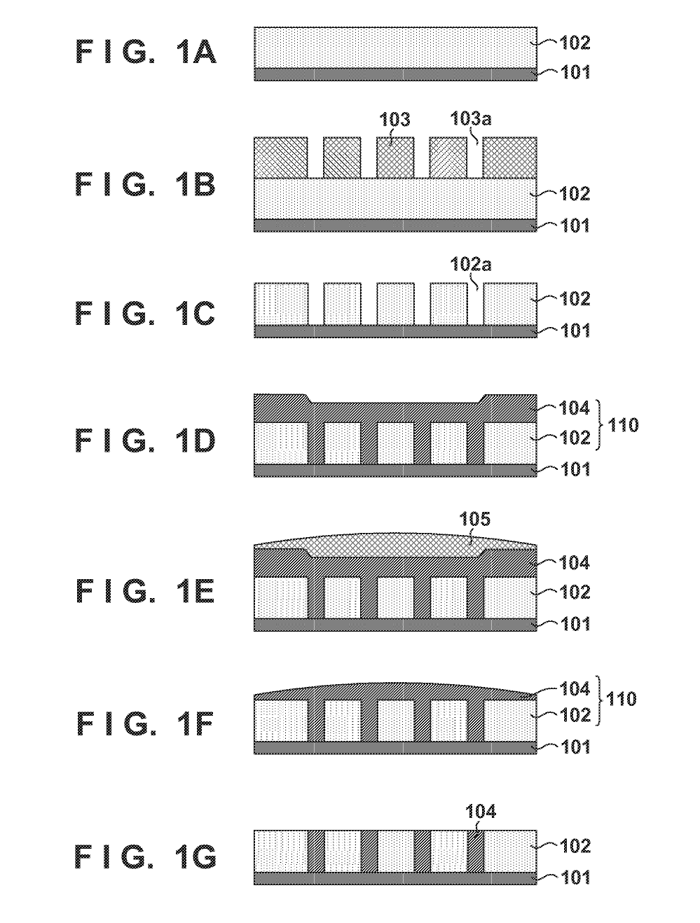

Now, steps of a planarization method according to a first embodiment will be described with reference to FIGS. 1A to 1G. First, as shown in FIG. 1A, an insulator layer 102 is formed on an underlayer 101. The underlayer 101 is, for example, a glass substrate, and elements may be formed on the glass substrate depending on the apparatus to be produced. Alternatively, the underlayer 101 may be another layer already formed on the substrate. The insulator layer 102 can be formed, for example, of an insulator material such as silicon oxide or silicon nitride.

Next, as shown in FIG. 1B, a resist pattern 103 is formed on the insulator layer 102. The resist pattern 103 has openings 103a. Next, as shown in FIG. 1C, the insulator layer 102 is etched with the resist pattern 103 thereon to form openings 102a in the insulator layer 102. Subsequently, the resist pattern 103 is removed. Next, as shown in FIG. 1D, the conductor layer 104 is formed on the insulator layer 102. The conductor layer 104 can be formed, for example, of metal such as aluminum, tungsten, titanium, or titanium nitride. Part of the conductor layer 104 enters the openings 102a of the insulator layer 102 and can function as vias.

A stacked member 110 including the insulator layer 102 and conductor layer 104 is formed in the steps described above. When CMP is applied to the stacked member 110 in this condition, excessive polishing known as erosion occurs in a high-density portion (central part of FIG. 1D) in the openings 102a of the insulator layer 102 in which the conductor is embedded. The excessive polishing is caused by variation in the polishing rate among respective locations of the stacked member 110. Thus, according to the present embodiment, as shown in FIG. 1E, a resist layer 105 varying in thickness is formed on the conductor layer 104. The thicknesses of the resist layer 105 at respective locations will be described later.

Next, as shown in FIG. 1F, the resist layer 105 and the upper part of the conductor layer 104 are removed by an etch-back process on the resist layer 105, and a top face of the conductor layer 104 is shaped. Here, etching is performed under conditions in which the etching rates of the resist layer 105 and conductor layer 104 will be approximately equal. An etched object is removed substantially uniformly by the etch-back process, and consequently the resist layer 105 before the etch-back process and the stacked member 110 after the etching have substantially equal top face geometries. Subsequently, as shown in FIG. 1G, the stacked member 110 is polished by CMP to planarize the top face of the stacked member 110.

According to the present embodiment, the stacked member 110 before polishing is formed such that amounts to be removed at respective locations of the stacked member 110 by polishing the stacked member 110 will correspond to the polishing rates at the respective locations of the stacked member 110. Consequently, a planar top face can be obtained by polishing. For example, the stacked member 110 is formed such that an amount of the stacked member 110 to be removed in central part of FIG. 1F where the polishing rate is high will be larger than an amount of the stacked member 110 to be removed in peripheral part of FIG. 1F where the polishing rate is low. The amount of the stacked member 110 to be removed corresponds to a distance between the top face of the stacked member 110 before polishing and the planar top face of the stacked member 110 after polishing.

To form the stacked member 110 in this way, the thicknesses of the resist layer 105 at respective locations are determined based on the polishing rate of the stacked member 110 and on a top face geometry of a layer (the conductor layer 104, according to the first embodiment) whose thickness is adjusted by the etch-back process via the resist layer 105. The thicknesses of the resist layer 105 are determined, for example, such that larger amounts of the resist layer 105 will be removed from locations where the polishing rate is higher. Also, the thicknesses of the resist layer 105 are determined such that smaller amounts of the resist layer 105 will be removed from locations where the top face of the conductor layer 104 is higher (farther away from the underlayer 101). The polishing rate of the stacked member 110 may vary globally throughout an entire polished film or vary locally. The present embodiment can improve planarity of polished surfaces in either case.

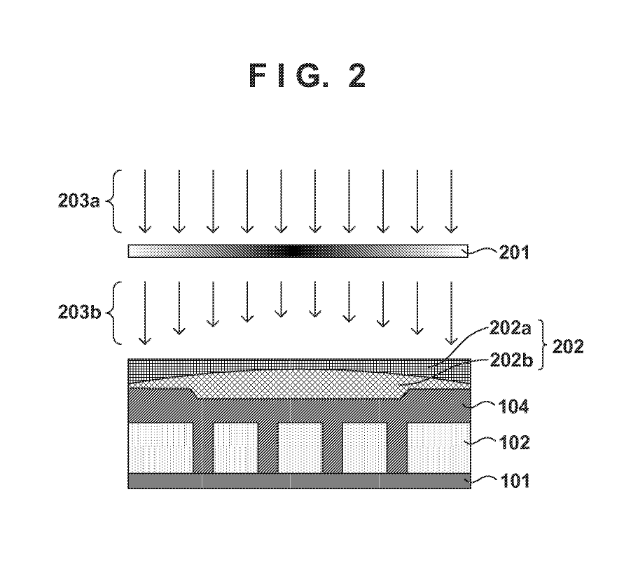

An example of a formation method for the resist layer 105 will be described with reference to FIG. 2. The resist layer 105 can be formed by a photolithography process using a multi tone mask 201. The multi tone mask is also referred to as a gradation mask. Also, the multi tone mask may be a gray scale mask. First, the conductor layer 104 is coated with resist 202. The resist 202 is a positive resist. Subsequently, the resist 202 is exposed to light using the multi tone mask 201. Arrows 203a indicate exposure light directed at the multi tone mask 201 and arrows 203b indicate the exposure light after passage through the multi tone mask 201. The lengths of the arrows represent intensities of the exposure light. Also, reference numeral 202a denotes that portion of the resist 202 which has been exposed and reference numeral 202b denotes that portion of the resist 202 which has not been exposed. As the resist 202 is developed after exposure, the exposed portion 202a is removed while the unexposed portion 202b is left to become the resist layer 105.

The multi tone mask 201 varies in light transmittance from one portion to another, and the exposure light passing through a position with higher transmittance exposes a deeper position of the resist 202, resulting in a smaller thickness of the resist 202 after development. The transmittance of respective portions of the multi tone mask 201 is determined based not only on the polishing rate of the stacked member 110, but also on parameters such as sensitivity characteristics of the resist used and etching selectivity between the resist and polished film.

With the planarization method described above, the resist layer 105 is formed, and then etched back to make adjustments such that an amount to be removed from the polished object, i.e., the stacked member 110, by polishing will be equivalent to a thickness corresponding to the polishing rate. This improves the planarity of the top face of the stacked member 110 after the polishing.

Although the stacked member 110 is formed of the insulator layer 102 and conductor layer 104 in the above example, instead of the conductor layer 104, an insulator layer different in material from the insulator layer 102 may be used in forming the stacked member 110. Different materials available for use include silicon oxide and silicon nitride. In this example, the insulator of another material embedded in the openings 102a of the insulator layer 102 can function as a light guide. Also, although the stacked member 110 is formed of two layers, i.e., the insulator layer 102 and conductor layer 104, the stacked member 110 may be formed of more than two layers including one or more other layers. The present embodiment is also applicable even to a member which does not have a stacked structure in a case where the member varies in polishing rate with location.

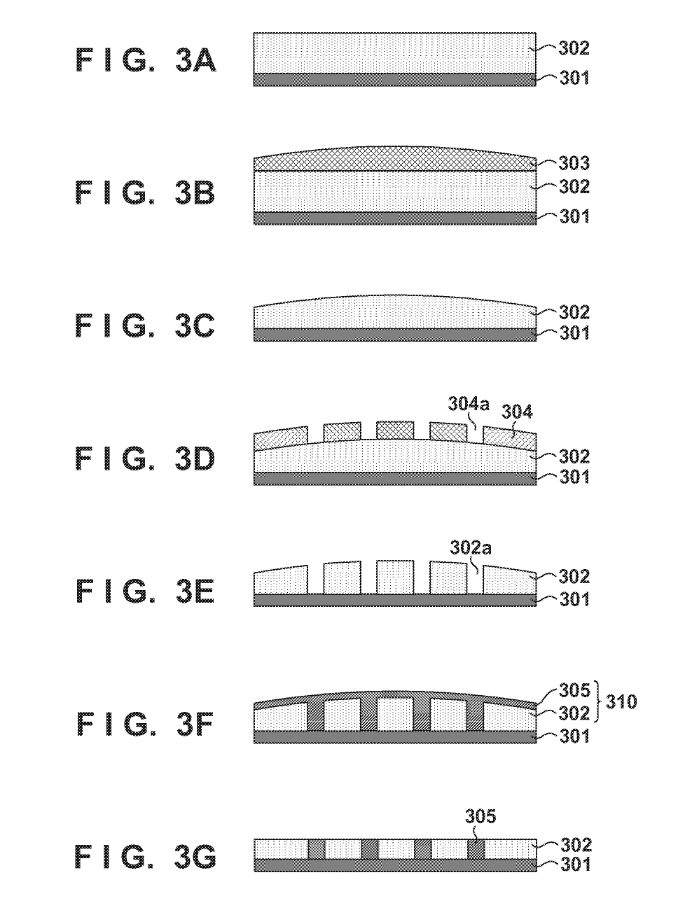

Now, steps of a planarization method according to a second embodiment will be described with reference to FIGS. 3A to 3G. First, as shown in FIG. 3A, an insulator layer 302 is formed on an underlayer 301. The underlayer 301 and insulator layer 302 may be similar to the underlayer 101 and insulator layer 102, and thus redundant description thereof will be omitted.

Next, as shown in FIG. 3B, a resist layer 303 varying in thickness with location is formed on the insulator layer 302. The thicknesses of the resist layer 303 at respective locations will be described later. The resist layer 303 can be formed using the method described with reference to FIG. 2.

Next, as shown in FIG. 3C, the resist layer 303 and the upper part of the insulator layer 302 are removed by an etch-back process on the resist layer 303. An etched object is removed substantially uniformly by the etch-back process, and consequently the resist layer 303 before the etch-back process and the insulator layer 302 after the etch-back process have substantially equal top face geometries. Here, etching is performed under conditions in which the etching rates of the resist layer 303 and insulator layer 302 will be approximately equal.

Next, as shown in FIG. 3D, a resist pattern 304 is formed on the insulator layer 302. The resist pattern 304 has openings 304a. Next, as shown in FIG. 3E, the insulator layer 302 is etched with the resist pattern 304 thereon to form openings 302a in the insulator layer 302, and then the resist pattern 304 is removed. Next, as shown in FIG. 3F, the conductor layer 305 is formed on the insulator layer 302. The conductor layer 305 can be similar to the conductor layer 104, and thus redundant description thereof will be omitted. Part of the conductor layer 305 enters the openings 302a of the insulator layer 302 and can function as vias.

A stacked member 310 including the insulator layer 302 and conductor layer 305 is formed in the steps described above. Subsequently, as shown in FIG. 3G, the stacked member 310 is polished by CMP to planarize the top face of the stacked member 310.

Thicknesses of the resist layer 303 at respective locations are determined in a manner similar to the first embodiment. According to the present embodiment, the stacked member 310 before polishing is also formed such that amounts to be removed at respective locations of the stacked member 310 by polishing the stacked member 310 will correspond to the polishing rates at the respective locations of the stacked member 310. To form the stacked member 310 in this way, the thicknesses of the resist layer 303 at respective locations are determined based on the polishing rate of the stacked member 310 and on a top face geometry of a layer (insulator layer 302, according to the second embodiment) whose thickness is adjusted by the etch-back process via the resist layer 303.

The present embodiment can also improve planarity of polished surfaces. According to the present embodiment, the resist pattern 304 is formed on the insulator layer 302 which is not planar. Therefore, the present embodiment may be adopted when the resist pattern 304 can be formed only to the extent that surface irregularities will not exceed the depth of focus of an exposure machine during exposure intended to form the resist pattern 304. Also, the resist layer 303 of FIG. 3B and resist pattern 304 of FIG. 3D may be formed as a single photoresist and etched simultaneously. The variation described in the first embodiment can also be adopted in the second embodiment.

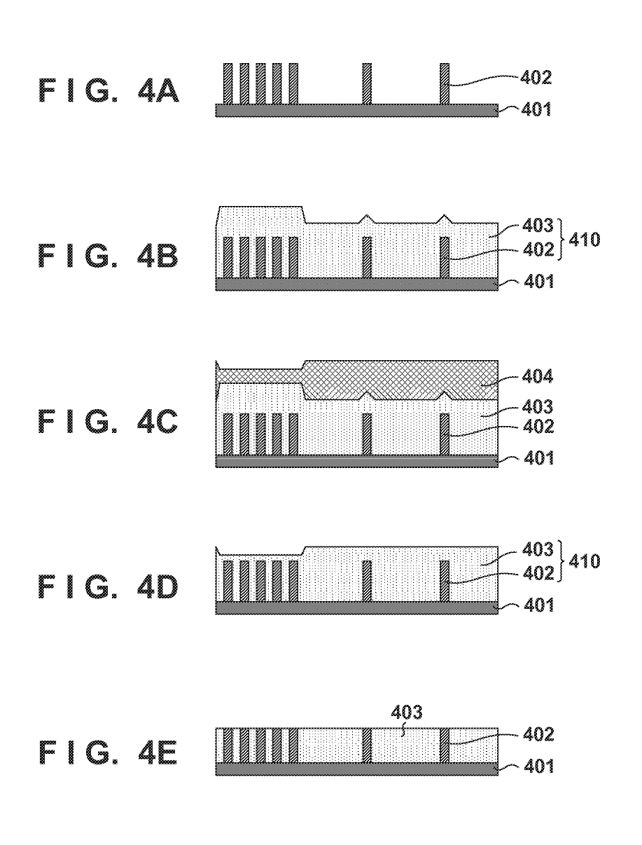

Now, steps of a planarization method according to a third embodiment will be described with reference to FIGS. 4A to 4E. First, as shown in FIG. 4A, a conductor layer 402 is formed on an underlayer 401. The underlayer 401 may be similar to the underlayer 101, and thus redundant description thereof will be omitted. The conductor layer 402 can be formed, for example, of metal such as aluminum, tungsten, titanium, or titanium nitride. For example, the conductor layer 402 has a conductive pattern.

Next, as shown in FIG. 4B, an insulator layer 403 is formed on the conductor layer 402. The insulator layer 403 can be formed, for example, of an insulator material such as silicon oxide or silicon nitride. Part of material of the insulator layer 403 enters gaps in the conductor layer 402 and can function as an interlayer insulation film. The conductor layer 402 and insulator layer 403 make up a stacked member 410.

When the stacked member 410 is polished as it is, a planar surface cannot be obtained depending on the position of the top face of the stacked member 410. Thus, as shown in FIG. 4C, the resist layer 404 is formed on the insulator layer 403. The resist layer 404 can be formed using the method described with reference to FIG. 2. Thicknesses of the resist layer 404 at respective locations are determined in a manner similar to the first and second embodiments. According to the present embodiment, the stacked member 410 before polishing is also formed such that amounts to be removed at respective locations of the stacked member 410 by polishing the stacked member 410 will correspond to the polishing rates at the respective locations of the stacked member 410. To form the stacked member 410 in this way, the thicknesses of the resist layer 404 at respective locations are determined based on the polishing rate of the stacked member 410 and on a top face geometry of a layer (insulator layer 403, according to the third embodiment) whose thickness is adjusted by the etch-back process via the resist layer 404.

Next, as shown in FIG. 4D, the resist layer 404 and the upper part of the insulator layer 403 are removed by an etch-back process on the resist layer 404. An etched object is removed substantially uniformly by the etch-back process, and consequently the resist layer 404 before the etch-back process and the insulator layer 403 after the etch-back process have substantially equal top face geometries. Subsequently, as shown in FIG. 4E, the stacked member 410 is polished by CMP to planarize the top face of the stacked member 410. According to the present embodiment, polishing may be carried out until the conductor layer 402 is revealed or ILD-CMP (inter-level dielectric chemical mechanical polishing) may be done by finishing the polishing before the conductor layer 402 is revealed.

The present embodiment can also improve planarity of polished surfaces. The variation described in the first embodiment can also be adopted in the third embodiment.

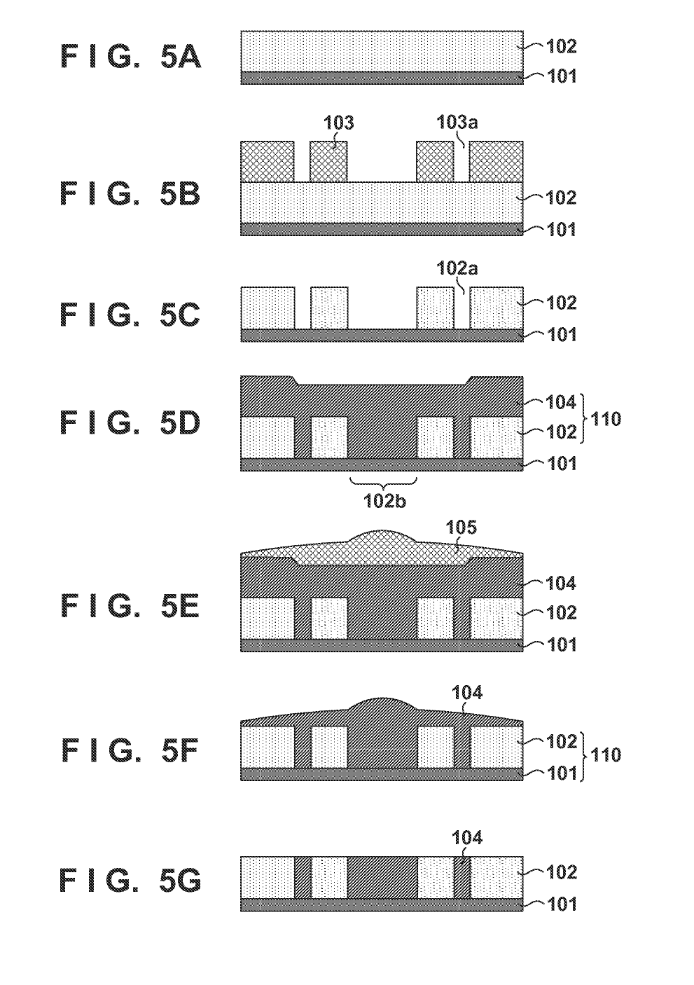

Now, steps of a planarization method according to a fourth embodiment will be described with reference to FIGS. 5A to 5G. The steps of the fourth embodiment shown in FIGS. 5A to 5G are similar to the steps of the first embodiment shown in FIGS. 1A to 1G, and thus redundant description thereof will be omitted. According to the fourth embodiment, the insulator layer 102 has a wide opening 102b as shown in FIG. 5D. When a stacked member including the insulator layer 102 provided with the opening 102b such as described above is polished without taking any measures, dishing occurs in a portion around the opening 102b. In the fourth embodiment, by forming a resist layer 105 varying in thickness with location as in the case of the first embodiment, it is possible to curb dishing. Although the fourth embodiment has been described based on the first embodiment, dishing can similarly be curbed by the second and third embodiments.

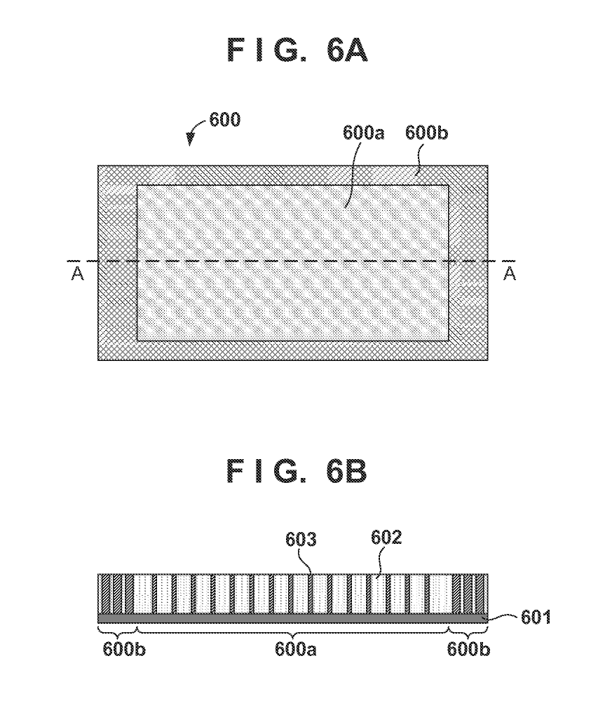

A method of manufacturing a solid-state image sensor according to a fifth embodiment will be described with reference to FIGS. 6A and 6B. FIG. 6A shows a solid-state image sensor 600 in process of production and FIG. 6B shows a sectional view taken along line A-A in FIG. 6A. The solid-state image sensor 600 includes a pixel section 600a in which pixels are formed and a circuit section 600b in which circuits adapted to control the operation of the pixels is formed. As shown in FIG. 6B, an insulating layer 602 and plugs 603 are formed on a semiconductor substrate 601 on which circuit elements are formed, the plugs 603 being embedded in the insulating layer 602. The pixel section 600a and circuit section 600b differ in the density of plugs 603, and according to the present embodiment, the circuit section 600b is higher in the density of plugs 603 than the pixel section 600a. In FIG. 6B, the plugs 603 in the pixel section 600a are designed to be thinner than the plugs 603 in the circuit section 600b. In this way, when the density of plugs 603 varies with location, so does the polishing rate. Thus, the planarity is improved if the top face of the insulating layer 602 and the top face of the plugs 603 are polished using any of the first to fourth embodiments described above. This reduces color irregularities and sensitivity irregularities of the solid-state image sensor 600. FIGS. 6A and 6B show an example of polishing the top face of a layer adjoining the semiconductor substrate 601, but the embodiments described above are also applicable to polishing of the top faces of other layers.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-108369, filed May 22, 2013, which is hereby incorporated by reference herein in its entirety.

What is claimed is:

1. A method of planarizing a member, comprising:
forming the member; and
polishing a top face of the member,
wherein the forming the member includes:
forming a resist layer which varies in thickness; and
performing an etch-back process,
wherein the etch-back process removes the resist layer and adjusts amounts to be removed by the polishing from respective locations of the member.

2. The method according to claim 1, wherein in the adjusting, an adjustment is performed such that the higher polishing rate of the member, the larger amount of the member to be removed.

3. The method according to claim 1, wherein:
in the forming the member, the member is formed by:
forming a first layer,
forming a second layer on the first layer,
forming the resist layer on the second layer, and
performing the etch-back process using the resist layer,
wherein in the polishing, a top face of the second layer is polished.

4. The method according to claim 1, wherein based on the polishing rate of the member and based on a top face geometry of the second layer before formation of the resist layer, thicknesses of the resist layer at respective locations are determined.

5. The method according to claim 1, wherein:
in the forming the member, the member is formed by:
forming a first layer,
forming the resist layer on the first layer,
performing the etch-back process using the resist layer, and
forming a second layer on the first layer an upper part of which has been removed by the etch-back process; and
in the polishing, a top face of the second layer is polished.

6. The method according to claim 5, wherein based on the polishing rate of the member and based on a top face geometry of the first layer before formation of the resist layer, thicknesses of the resist layer at respective locations are determined.

7. The method according to claim 3, wherein the first layer is formed of an insulator and the second layer is formed of a conductor.

8. The method according to claim 3, wherein the first layer is formed of an insulator and the second layer is formed of an insulator made of a material different from that of the first layer.

9. The method according to claim 7, wherein the first layer has an opening and material of the second layer is embedded in the opening when the second layer is formed.

10. The method according to claim 3, wherein the first layer is formed of a conductor and the second layer is formed of an insulator.

11. The method according to claim 7, wherein the polishing is carried out until the first layer is exposed.

12. The method according to claim 10, wherein the polishing is finished before the first layer is exposed.

13. The method according to claim 1, wherein the resist layer is formed by photolithography using a multi tone mask.

14. The method according to claim 1, wherein the polishing is performed by chemical mechanical polishing.

15. The method according to claim 1, wherein the method is performed as part of a method of manufacturing a solid-state image sensor.
